(19) United States
(12) Patent Application Publication
(10) Pub. No.: US 2024/0158915 A1
(43) Pub. Date: May 16, 2024

(54) COMPOSITION FOR ATOMIC LAYER DEPOSITION OF HIGH QUALITY SILICON OXIDE THIN FILMS

(71) Applicant: VERSUM MATERIALS US, LLC, TEMPE, AZ (US)

(72) Inventors: HARIPIN CHANDRA, SAN MARCOS, CA (US); STEVEN G. MAYORGA, OCEANSIDE, CA (US); XINJIAN LEI, VISTA, CA (US)

(21) Appl. No.: 18/550,932

(22) PCT Filed: Feb. 23, 2022
(86) PCT No.: PCT/US22/17475

§ 371 Date: Sep. 15, 2023

(51) Int. Cl. C23C 16/455; C23C 16/40

(52) U.S. Cl. CPC C23C 16/45553; C23C 16/401

(57) ABSTRACT

Atomic layer deposition (ALD) process formation of silicon oxide with temperature <600° C. is disclosed. Silicon precursors used have a formula of:

Formula I: H₃ SiNR¹R² wherein R¹ and R² are each independently selected from a C₁₋₁₀ linear alkyl group, a C₃₋₁₀ branched alkyl group, a C₃₋₁₀ cyclic alkyl group, a C₂₋₁₀ alkenyl group, a C₄₋₁₀ aromatic group, a C₄₋₁₀ heterocyclic group with a provisio that R¹ and R² cannot be both C₁₋₂ linear alkyl group or C₃ branched alkyl group, and wherein the silicon precursors are free of one or more impurities selected from the group consisting of halide compounds, metal ions, metals, and combinations thereof.

### CROSS-REFERENCE TO RELATED APPLICATION

This application is a National Stage filing under 35 U.S.C. 371 of International Patent Application No. PCT/US2022/017475, filed Feb. 23, 2022, which claims priority to US Patent Application having Ser. No. 63/200,629 filed on Mar. 18, 2021. The entire contents of these applications are incorporated herein by reference in their entirety.

### BACKGROUND OF THE INVENTION

Described herein is a composition for the formation of a high quality silicon oxide film. More specifically, described herein is a composition and method for formation of a silicon oxide film at one or more deposition temperatures of about 600° C. or lower using an atomic layer deposition (ALD) process.

Organoaminosilanes containing the —SiH₃ moieties are desirable precursors for the deposition of silicon-containing films such as, without limitation, silicon oxide and silicon nitride films or doped versions thereof. For example, volatile compounds such as without limitation organoaminosilanes, organoaminodisilanes, and/or organoaminocarbosilanes are important precursors used for the deposition of silicon-containing films in the manufacture of semiconductor devices. Particular embodiments of organoaminosilane compounds include di-iso-propylaminosilane (DIPAS) and di-sec-butylaminosilane (DSBAS), which have previously been shown to exhibit desirable physical properties for the controlled deposition of such films.

The prior art describes some methods for the production of organoaminosilane compounds. Japanese Patent JP49-1106732 describes a method for preparing silylamines by the reaction of an imine and a hydridosilane in the presence of a rhodium (Rh) complex. Exemplary silylamines that were prepared include: PhCH₂N(Me)SiEt₃, PhCH₂N(Me)SiHPh₂, PhCH₂N(Ph)SiEt₃, and PhMeCHN(Ph)SiHEt₂ wherein “Ph” means phenyl, “Me” means methyl, and “Et” means ethyl.

U.S. Pat. No. 6,072,085 describes a method for preparing a secondary amine from a reaction mixture comprising an imine, a nucleophilic activator, a silane, and a metal catalyst. The catalyst acts to catalyze the reduction of the imine by a hydrosilylation reaction.

U.S. Pat. No. 6,963,003, which is owned by the assignee of the present application, provides a method for preparing an organoaminosilane compound comprising reacting a stoichiometric excess of at least one amine selected from the group consisting of secondary amines having the formula R¹R²NH, primary amines having the formula R²NH₂ or combinations thereof with at least one chlorosilane having the formula R³ₙSiCl₄₋ₙ under anhydrous conditions sufficient such that a liquid comprising the aminosilane product and an amine hydrochloride salt is produced wherein R¹ and R² can each independently be a linear, cyclic or branched alkyl group having 1 to 20 carbon atoms; R³ can be a hydrogen atom, an amine group, or a linear, cyclic or branched alkyl group having 1 to 20 carbon atoms; and n is a number ranging from 1 to 3.

U.S. Pat. No. 7,875,556, which is owned by the assignee of the present application, describes a method for making an organoaminosilane by reacting an acid with an arylsilane in the presence of a solvent, adding a secondary amine and tertiary amine, and removing the reaction byproduct using phase separation and the solvent using distillation.

U.S. Publ. No. 2012/0277457, which is owned by the assignee of the present application, describes a method for making an organoaminosilane compound having the following formula:

H₃SiNR¹R²

wherein R¹ and R² are each independently selected from C₁-C₁₀ linear, branched or cyclic, saturated or unsaturated, aromatic, heterocyclic, substituted or unsubstituted alkyl groups wherein R¹ and R² are linked to form a cyclic group or wherein R¹ and R² are not linked to form a cyclic group comprising the steps of: reacting a halosilane having the formula HₙSiX₄₋ₙ wherein n is 0, 1, or 2 and X is Cl, Br, or a mixture of Cl and Br, with an amine to provide a slurry comprising a haloaminosilane compound X₄₋ₙHₙ₋₁SiNR¹R² wherein n is a number selected from 1, 2 and 3; and X is a halogen selected from Cl, Br, or a mixture of Cl and Br; and introducing into the slurry a reducing agent wherein at least a portion of the reducing agent reacts with the haloaminosilane compound and provides an end product mixture comprising the aminosilane compound.

Korean Patent No. 10-1040325 provides a method for preparing an alkylaminosilane which involves reacting a secondary amine and trichloroalkylsilane in an anhydrous atmosphere and in the presence of a solvent to form an alkyl aminochlorosilane intermediate and a metal hydride LiAlH₄ is added to the alkyl aminochlorosilane intermediate as a reducing agent to form the alkylaminosilane. The alkylaminosilane is then subjected to a distillation process to separate and purify the alkylaminosilane.

Reference article entitled “Homogeneous Catalytic Hydrosilylation of Pyridines”, L. Hao et al., Angew. Chem., Int. Ed., Vol. 37, 1998, pp. 3126-29 describes the hydrosilylation of pyridines, e.g. RC₅H₄N (R=H, 3-Me, 4-Me, 3-CO₂Et), by PhSiH₂Me, Ph₂SiH₂ and PhSiH₃ in the presence of a titanocene complex catalyst such as a [Cp₂TiMe₂], which provided high yields of 1-silylated tetrahydropyridine derivatives and the intermediate silyltitanocene adduct, Cp₂Ti(SiHMePh)(C₅H₅N) (I).

Reference article entitled “Stoichiometric Hydrosilylation of Nitriles and Catalytic Hydrosilylation of Imines and Ketones Using a μ-Silane Diruthenium Complex”, H. Hashimoto et al., Organometallics, Vol. 22, 2003, pp. 2199-2201 describes a method to synthesize μ-iminosilyl complexes Ru₂(CO)₄(μ-dppm)(μ-SiToI₂)(μ-RCH:NSiToI₂) (R=Me, Ph, t-Bu, CH:CH₂) in high yields during the stoichiometric reactions of a diruthenium complex having Ru—H—Si interactions, {Ru(CO)₂(SiToI₂H)}₂(μ-dppm)(μ-η²:η²-H₂SiToI₂), with nitriles RCN.

Reference article entitled “Titanocene-Catalyzed Hydrosilylation of Imines: Experimental and Computational Investigations of the Catalytically Active Species”, H. Gruber-Woelfler et al., Organometallics, Vol. 28, 2009, pp. 2546-2553 described the asymmetrical catalytic hydrosilylation of imines using (R,R)-ethylene-1,2-bis(η⁵-4,5,6,7-tetrahydro-1-indenyl)titanium (R)-1,1′-binaphth-2-olate (1) and (S,S)-ethylene-1,2-bis(η⁵-4,5,6,7-tetrahydro-1-indenyl)titanium dichloride (2) as catalyst precursors. After activation with RLi (R=alkyl, aryl) and a silane, these complexes are known catalysts for hydrosilylation reactions.

Reference article “Iridium-Catalyzed Reduction of Secondary Amides to Secondary Amines and Imines by Diethylsilane”, C. Cheng et al., J. Am. Chem. Soc. , Vol. 134, 2012, pp. 110304-7, describes the catalytic reduction of secondary amides to imines and secondary amines by using iridium catalysts such as [Ir(COE)₂Cl]₂ with diethylsilane as reductant.

There is a need to develop a process for forming a high quality, low impurity, high conformal silicon oxide film using an atomic layer deposition (ALD) process or an ALD-like process, such as without limitation a cyclic chemical vapor deposition process, to replace thermal-based deposition processes. Further, it is desirable to develop a high temperature deposition (e.g., deposition at one or more temperatures of 600° C.) to improve one or more film properties, such as purity and/or density, in an ALD or ALD-like process.

### BRIEF SUMMARY OF THE INVENTION

Described herein is a process for the deposition of a silicon oxide material or film at high temperatures, e.g., at one or more temperatures of 600° C. or lower, in an atomic layer deposition (ALD) or an ALD-like process.

One embodiment, disclosed is a process for depositing a silicon oxide film onto a substrate comprising the steps of: a. providing a substrate in a reactor; b. introducing into the reactor a silicon precursor having a formula of H₃SiNR¹R², wherein R¹ and R² are each independently selected from methyl, ethyl, iso-propyl, sec-butyl, tert-butyl, tert-pentyl phenyl, tolyl, cyclohexyl, cyclopentyl wherein the silicon precursor is substantially free of one or more impurities selected from the group consisting of halide compounds, metal ions, metals, and combinations thereof; c. purging the reactor with purge gas; d. introducing an oxygen source into the reactor; e. purging the reactor with purge gas, wherein steps b through e are repeated until a desired thickness is deposited, and wherein a process temperature ranges from 20 to 600° C. and a pressure in the reactor ranges from 50 milliTorr (mT) to 760 Torr.

Such a process according to the invention forms a high quality silicon oxide film having at least one or more of the following attributes: a density of about 2.1 g/cc or greater, low chemical impurity, and/or high conformality in a plasma enhanced atomic layer deposition (ALD) process or a plasma enhanced ALD-like process using cheaper, reactive, and more stable organoaminosilanes. Most importantly, the silicon oxide films disclosed herein have a leakage current about 2.0e⁻⁸ A/cm² or lower at 2.5 MW/cm², or about 2.0e⁻⁹ A/cm² or lower at 2.5 MV/cm², or about 1.0e⁻⁹ A/cm² or lower at 2.5 MV/cm².

Other features and advantages of the present invention will be apparent from the following more detailed description of the preferred embodiment, taken in conjunction with the accompanying drawings which illustrate, by way of example, the principles of the invention. The embodiments and features of the present invention can be used alone or in combinations with each other.

### BRIEF DESCRIPTION OF THE DRAWING

FIG. 1 is a plot graph that provides degradation of di-sec-butylaminosilane vs chloride concentrations, demonstrating that higher chloride concentrations cause DSBAS to degrade more than DSBAS having lowe chloride concentrations and it is desirable to have silicon precursors having 10 ppm chloride or less.

### DETAILED DESCRIPTION OF THE INVENTION

Described herein are compositions and processes related to the formation of a silicon oxide containing film, such as a silicon oxynitride film, a stoichiometric or non-stoichiometric silicon oxide film, a silicon oxide film or combinations thereof at one or more temperatures of 600° C. or lower, preferably 500° C. or lower, most preferably 400° C. or lower, in an atomic layer deposition (ALD) or in an ALD-like process, such as without limitation a cyclic chemical vapor deposition process (CCVD). The deposition (e.g., one or more depositions at temperatures ranging from about 20 to 600° C.) methods described herein provide films or materials that exhibit at least one or more of the following advantages: a density of about 2.1 g/cm³ or greater, low chemical impurity, high conformality in a thermal atomic layer deposition, a plasma enhanced atomic layer deposition (ALD) process or a plasma enhanced ALD-like process. Importantly, the deposited silicon oxide has a leakage current about 2.0e⁻⁸ A/cm² or lower at 2.5 MW/cm², or about 2.0e⁻⁹ A/cm² or lower at 2.5 MV/cm², or about 1.0e⁻⁹ A/cm² or lower at 2.5 MV/cm².

Typical ALD processes in the prior art use an oxygen source, or oxidizer such as oxygen, oxygen plasma, water vapor, water vapor plasma, hydrogen peroxide, or ozone to form SiO₂ at process temperatures ranging from 25 to 600° C. The deposition steps comprises of:
a. providing a substrate in a reactor
b. introducing into the reactor a silicon precursor
c. purging reactor with purge gas
d. introducing oxygen source into the reactor; and
e. purging reactor with purge gas.

In such prior art process, steps b through e are repeated until desired thickness of film is deposited.

In one embodiment, the silicon precursor described herein is a compound having the following Formula I: H₃SiNR¹R² wherein R¹ and R² are each independently selected from a C₁₋₁₀ linear alkyl group, a C₃₋₁₀ branched alkyl group, a C₃₋₁₀ cyclic alkyl group, a C₂₋₁₀ alkenyl group, a C₄₋₁₀ aromatic group, a C₄₋₁₀ heterocyclic group with a proviso that R¹ and R² cannot be both C₁₋₂ linear alkyl groups (Me or Et) or C₃ branched alkyl group (iso-propyl). Preferred examples of R¹ and R² are each independently selected from the group consisting of sec-butyl, tert-butyl, tert-pentyl phenyl, tolyl, cyclohexyl, cyclopentyl. The silicon precusor is substantially free of one or more impurities selected from the group consisting of halide compounds, metal ions, metals, and combinations thereof. In certain embodiments, substituents R¹ and R² in Formula I can be linked together to form a ring structure. In these embodiments, the ring structure can be saturated such as, for example, a cyclic alkyl ring, or unsaturated, for example, an aryl ring.

Examples of precursors having Formula I include are but not limited to: di-iso-propylaminosilane, di-sec-butylaminosilane, di-tert-butylaminosilane, phenylmethylaminosilane, phenylethylaminosilane, cyclohexamethylaminosilane, cyclohexaethyaminolsilane, 2,6-dimethylpiperidinosilane, 2,5-dimethylpyrrolylsilane and mixtures thereof.

The precursors of Formula I can be produced by following reaction equation (1):

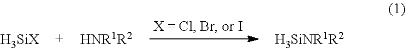

The reaction in Equations (1) can be conducted with (e.g., in the presence of) or without (e.g., in the absence of) organic solvents. In embodiments wherein an organic solvent is used, examples of suitable organic solvents include, but are not limited to, hydrocarbon such as hexanes, octane, toluene, and ethers such as diethylether and tetrahydrofuran (THF). In these or other embodiments, the reaction temperature is in the range of from about −70° C. to the boiling point of the solvent employed if a solvent is used. The resulting silicon precursor compound can be purified, for example, via vacuum distillation after removing all by-products as well as any solvent(s) if present.

Compositions according to the present invention that are substantially free of halides can be achieved by (1) reducing or eliminating halides during chemical synthesis, and/or (2) implementing an effective purification process to remove halides from the crude product such that the final purified product is substantially free of halides. Halide sources may be reduced during synthesis by using reagents that do not contain halides such as chlorosilanes, bromosilanes, or iodosilanes thereby avoiding the production of by-products that contain halide ions. In addition, the aforementioned reagents should be substantially free of chloride impurities such that the resulting crude product is substantially free of chloride impurities. In a similar manner, the synthesis should not use halide based solvents, catalysts, or solvents which contain unacceptably high levels of halide contamination. The crude product may also be treated by various purification methods to render the final product substantially free of halides such as chlorides. Such methods are well described in the prior art and, may include, but are not limited to, purification processes such as distillation, or adsorption. Distillation is commonly used to separate impurities from the desired product by exploiting differences in boiling point. Adsorption may also be used to take advantage of the differential adsorptive properties of the components to effect separation such that the final product is substantially free of halide. Adsorbents such as, for example, commercially available MgO—Al₂O₃ blends can be used to remove halides such as chloride.

Equation (1) is an exemplary synthetic route to make the silicon precursor compound having Formula I involving a reaction between halidotrialkylsilane and a primary or secondary amine as described in literatures. Other synthetic routes such as equations (2) or (3) may be also employed to make these silicon precursor compounds having Formula I as disclosed in the prior art.

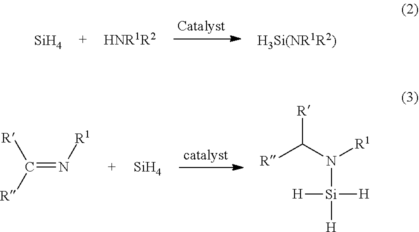

wherein the imine reagents may include secondary aldimines, R¹—N═CHR′, or secondary ketimines, R¹—N═CR′R″, containing linear or branched organic R¹, R′ and R″ functionalities and wherein R¹, R′ and R″ are each independently selected from hydrogen, a C₁₋₁₀ linear alkyl group, a C₃₋₁₀ branched alkyl group, a C₃₋₁₀ cyclic alkyl group, a C₂₋₁₀ alkenyl group, a C₄₋₁₀ aromatic group, a C₄₋₁₀ heterocyclic group, though it is preferable that alkyl functionalities be sufficiently large to afford stability during purification processes and storage of the final organoaminosilane product. Exemplary imines include, but are not limited to, N-iso-propyl-iso-propylidenimine, N-iso-propyl-sec-butylidenimine, N-sec-butyl-sec-butylidenimine, and N-tert-butyl-iso-propylidenimine.

The catalyst employed in the method of the present invention is one that promotes the formation of a silicon-nitrogen bond, i.e., dehydro-coupling catalyst. Exemplary catalysts that can be used with the method described herein include, but are not limited to the following: alkaline earth metal catalysts; halide-free main group, transition metal, lanthanide, and actinide catalysts; and halide-containing main group, transition metal, lanthanide, and actinide catalysts.

Exemplary alkaline earth metal catalysts include but are not limited to the following: Mg[N(SiMe₃)₂]₂, To^{M}MgMe [To^{M}=tris(4,4-dimethyl-2-oxazolinyl)phenylborate], To^{M}Mg-H, To^{M}Mg-NR₂ (R=H, alkyl, aryl) Ca[N(SiMe₃)₂]₂, [(dipp-nacnac)CaX(THF)]₂ (dipp-nacnac=CH[(CMe)(2,6-ⁱPr₂-C₆H₃N)]₂; X=H, alkyl, carbosilyl, organoamino), Ca(CH₂Ph)₂, Ca(C₃H₅)₂, Ca(α-Me₃Si-2-(Me₂N)-benzyl)₂(THF)₂, Ca(9-(Me₃Si)-fluorenyl)(α-Me₃Si-2-(Me₂N)-benzyl)(THF), [(Me₃TACD)₃Ca₃(μ³-H)₂]⁺ (Me₃TACD=Me₃[12]aneN₄), Ca(η²-Ph₂CNPh)(hmpa)=(hmpa=hexamethylphosphoramide), Sr[N(SiMe₃)₂]₂, and other M²⁺ alkaline earth metal-amide, -imine, -alkyl, -hydride, and -carbosilyl complexes (M=Ca, Mg, Sr, Ba).

Exemplary halide-free, main group, transition metal, lanthanide, and actinide catalysts include but are not limited to the following: 1,3-di-iso-propyl-4,5-dimethylimidazol-2-ylidene, 2,2′-bipyridyl, phenanthroline, B(C₆F₅)₃, BR₃ (R=linear, branched, or cyclic C₁ to C₁₀ alkyl group, a C₅ to C₁₀ aryl group, or a C₁ to C₁₀ alkoxy group), AIR₃ (R=linear, branched, or cyclic C₁ to C₁₀ alkyl group, a C₅ to C₁₀ aryl group, or a C₁ to C₁₀ alkoxy group), (C₅H₅)₂TiR₂ (R=alkyl, H, alkoxy, organoamino, carbosilyl), (C₅H₅)₂Ti(OAr)₂[Ar=(2,6-(ⁱPr)₂C₆H₃)], (C₅H₅)₂Ti(SiHRR′)PMe₃ (wherein R, R′ are each independently selected from H, Me, Ph), TiMe₂(dmpe)₂ (dmpe=1,2-bis(dimethylphosphino)ethane), bis(benzene)chromium(0), Cr(CO)₆, Mn₂(CO)₁₂, Fe(CO)₅, Fe₃(CO)₁₂, (C₅H₅)Fe(CO)₂Me, Co₂(CO)₈, Ni(II) acetate, Nickel(II) acetylacetonate, Ni(cyclooctadiene)₂, [(dippe)Ni(μ-H)]₂ (dippe=1,2-bis(di-iso-propylphosphino)ethane), (R-indenyl)Ni(PR′₃)Me (R=1-ⁱPr, 1-SiMe₃, 1,3-(SiMe₃)₂; R′=Me,Ph), [{Ni(η-CH₂:CHSiMe₂)₂O}₂{μ-(η-CH₂:CHSiMe₂)₂O}], Cu(I) acetate, CuH, [tris(4,4-dimethyl-2-oxazolinyl)phenylborate]ZnH, (C₅H₅)₂ZrR₂ (R=alkyl, H, alkoxy, organoamino, carbosilyl), Ru₃(CO)₁₂, [(Et₃P)Ru(2,6-dimesitylthiophenolate)][B[3,5-(CF₃)₂C₆H₃]₄], [(C₅Me₅)Ru(R₃P)ₓ(NCMe)₃₋ₓ]⁺ (wherein R is selected from a linear, branched, or cyclic C₁ to C₁₀ alkyl group and a C₅ to C₁₀ aryl group; x=0, 1, 2, 3), Rh₆ (CO)₁₆, tris(triphenylphosphine)rhodium(I)carbonyl hydride, Rh₂H₂(CO)₂(dppm)₂ (dppm=bis(diphenylphosphino)methane, Rh₂(μ-SiRH)₂(CO)₂(dppm)₂ (R=Ph, Et, C₆H₁₃), Pd/C, tris(dibenzylideneacetone)dipalladium(0), tetrakis(triphenylphosphine)palladium(0), Pd(II) acetate, (C₅H₅)₂SmH, (C₅Me₅)₂SmH, (THF)₂Yb[N(SiMe₃)₂]₂, (NHC)Yb(N(SiMe₃)₂)₂ [NHC=1,3-bis(2,4,6-trimethylphenyl) imidazol-2-ylidene)], Yb(η²-Ph₂CNPh)(hmpa)₃ (hmpa=hexamethylphosphoramide), W(CO)₆, Re₂(CO)₁₀, Os₃(CO)₁₂, Ir₄(CO)₁₂, (acetylacetonato)dicarbonyliridium(I), Ir(Me)₂(C₅Me₅)L (L=PMe₃, PPh₃), [Ir(cyclooctadiene)OMe]₂, PtO₂ (Adams's catalyst), platinum on carbon (Pt/C), ruthenium on carbon (Ru/C), palladium on carbon, nickel on carbon, osmium on carbon, Platinum(0)-1,3-divinyl-1,1,3,3-tetramethyldisiloxane (Karstedt's catalyst), bis(tri-tert-butylphosphine)platinum(0), Pt(cyclooctadiene)₂, [(Me₃Si)₂N]₃U][BPh₄], [(Et₂N)₃U][BPh4], and other halide-free Mⁿ⁺ complexes (M=Sc, Ti, V, Cr, Mn, Fe, Co, Ni, Cu, Zn, Y, Zr, Nb, Mo, Ru, Rh, Pd, La, Ce, Pr, Nd, Pm, Sm, Eu, Gd, Tb, Dy, Ho, Er, Tm, Yb, Lu, Hf, Ta, W, Re, Os, Ir, Pt, U; n=0, 1, 2, 3, 4, 5, 6).

Exemplary halide-containing, main group, transition metal, lanthanide, and actinide catalysts include but are not limited to the following: BX₃ (X=F, CI, Br, I), BF₃·Et₂, AlX₃ (X=F, CI, Br, I), (C₅H₅)₂TiX₂ (X=F, Cl), [Mn(CO)₄Br]₂, NiCl₂, (C₅H₅)₂ZrX₂ (X=F, Cl), PdCl₂, Pdl₂, CuCl, Cul, CuF₂, CuCl₂, CuBr₂, Cu(PPh₃)₃Cl, ZnCl₂, [(C₆H₆)RuX₂]₂ (X=Cl, Br, I), (Ph₃P)₃RhCl (Wilkinson's catalyst), [RhCl(cyclooctadiene)]₂, di-μ-chloro-tetracarbonyldirhodium(I), bis(triphenylphosphine)rhodium(I) carbonyl chloride, Ndl₂, Sml₂, Dyl₂, (POCOP)IrHCl (POCOP=2,6-(R₂PO)₂C₆H₃; R=ⁱPr, ⁿBu, Me), H₂PtCl₆·nH₂O (Speier's catalyst), PtCl₂, Pt(PPh₃)₂Cl₂, and other halide-containing Mⁿ⁺ complexes (M=Sc, Ti, V, Cr, Mn, Fe, Co, Ni, Cu, Zn, Y, Zr, Nb, Mo, Ru, Rh, Pd, La, Ce, Pr, Nd, Pm, Sm, Eu, Gd, Tb, Dy, Ho, Er, Tm, Yb, Lu, Hf, Ta, W, Re, Os, Ir, Pt, U; n=0, 1, 2, 3, 4, 5, 6).

It is believed that significant levels of chloride and metal ions or metal impurities in the silicon precursor compounds having Formula I may be introduced into the resulting silicon oxide film when used as precursor for atomic layer deposition, and thus can be detrimental to the device performance such as higher leakage current. The silicon precursor compounds having Formula I according to the present invention and compositions comprising the silicon precursor compounds having Formula I according to the present invention are preferably substantially free of halide. As used herein, the term “substantially free” as it relates to halide compounds, for example, chlorides (i.e. chloride-containing species such as HCl or silicon compounds having at least one Si—Cl bond such as H₃SiCl) and fluorides, bromides, and iodides, means less than 10 ppm chloride or less (by weight) measured by ion chromatography (IC), preferably less than 5 ppm chloride or less measured by ion chromatography (IC), and more preferably less than 2 ppm or less chloride measured by ion chromatography (IC), and most preferably less than 1 ppm chloride or less as measured by ion chromatography (IC). In some embodiments, the silicon precursor compounds having Formula I are free of metal ions such as Li⁺, Ca²⁺, Al³⁺, Fe²⁺, Fe³⁺, Ni²⁺, Cr³⁺. As used herein, the term “free of” as it relates to Li, Ca, Al, Fe, Ni, Cr, noble metal such as Ru or Pt (ruthenium (Ru) or platinum (Pt) from the catalysts used in the synthesis), means less than 1 ppm (by weight) as measured by ICP-MS, preferably less than 0.1 ppm as measured by ICP-MS, and more preferably less than 0.01 ppm as measured by ICP-MS, and most preferably 1 ppb as measured by ICP-MS. In addition, the silicon precursor compounds having Formula I are also preferably substantially free of silicon-containing impurities such as alkylsiloxanes which may have impact on the growth, for example hexamethyldisiloxane.

In certain embodiments, the silicon films deposited using the methods described herein are formed in the presence of oxygen using an oxygen source, reagent or precursor comprising oxygen. An oxygen source may be introduced into the reactor in the form of at least one oxygen source and/or may be present incidentally in the other precursors used in the deposition process. Suitable oxygen source gases may include, for example, water (H₂O (e.g., deionized water, purifier water, and/or distilled water), oxygen (O₂), mixture of oxygen and hydrogen, oxygen plasma, ozone (O₃), N₂O, NO₂, carbon monoxide (CO), carbon dioxide (CO₂), carbon dioxide (CO₂) plasma, carbon monoxide (CO) plasma, N₂O plasma, NO₂ plasma and combinations thereof. In certain embodiments, the oxygen source comprises an oxygen source gas that is introduced into the reactor at a flow rate ranging from about 1 to about 2000 standard cubic centimeters (sccm) or from about 1 to about 1000 sccm. The oxygen source can be introduced for a time that ranges from about 0.1 to about 100 seconds. In one particular embodiment, the oxygen source comprises water having a temperature of 10° C. or greater. In embodiments wherein the film is deposited by an ALD or a cyclic CVD process, the precursor pulse can have a pulse duration that is greater than 0.01 seconds, and the oxygen source can have a pulse duration that is less than 0.01 seconds, while the water pulse duration can have a pulse duration that is less than 0.01 seconds.

The deposition methods disclosed herein may involve one or more purge gases. The purge gas, which is used to purge away unconsumed reactants and/or reaction byproducts, is an inert gas that does not react with the silicon precursors. Exemplary purge gases include, but are not limited to, argon (Ar), nitrogen (N₂), helium (He), neon (Ne), hydrogen (H₂), and mixtures thereof. In certain embodiments, a purge gas such as Ar is supplied into the reactor at a flow rate ranging from about 10 to about 2000 sccm for about 0.1 to 1000 seconds, thereby purging the unreacted material and any byproduct that may remain in the reactor.

The respective step of supplying the precursors, oxygen source, the nitrogen-containing source, and/or other precursors, source gases, and/or reagents may be performed by changing the time for supplying them to change the stoichiometric composition of the resulting dielectric film.

Energy is applied to the at least one of the silicon precursor, oxygen containing source, or combination thereof to induce reaction and to form the dielectric film or coating on the substrate. Such energy can be provided by, but not limited to, thermal, plasma, pulsed plasma, helicon plasma, high density plasma, inductively coupled plasma, X-ray, e-beam, photon, remote plasma methods, and combinations thereof. In certain embodiments, a secondary RF frequency source can be used to modify the plasma characteristics at the substrate surface. In embodiments wherein the deposition involves plasma, the plasma-generated process may comprise a direct plasma-generated process in which plasma is directly generated in the reactor, or alternatively a remote plasma-generated process in which plasma is generated outside of the reactor and supplied into the reactor.

The at least one silicon precursors may be delivered to the reaction chamber such as a cyclic CVD or ALD reactor in a variety of ways. In one embodiment, a liquid delivery system may be utilized. In an alternative embodiment, a combined liquid delivery and flash vaporization process unit may be employed, such as, for example, the turbo vaporizer manufactured by MSP Corporation of Shoreview, MN, to enable low volatility materials to be volumetrically delivered, which leads to reproducible transport and deposition without thermal decomposition of the precursor. In liquid delivery formulations, the precursors described herein may be delivered in neat liquid form, or alternatively, may be employed in solvent formulations or compositions comprising same. Thus, in certain embodiments the precursor formulations may include solvent component(s) of suitable character as may be desirable and advantageous in a given end use application to form a film on a substrate.

For those embodiments wherein the at least one silicon precursor precursor(s) having Formula I is used in a composition comprising a solvent and at least one silicon precursor having Formula I described herein, the solvent or mixture thereof selected does not react with the silicon precursor. The amount of solvent by weight percentage in the composition ranges from 0.5% by weight to 99.5% or from 10% by weight to 75%. In this or other embodiments, the solvent has a boiling point (b.p.) similar to the b.p. of the at least one silicon precursor of Formula I or the difference between the b.p. of the solvent and the b.p. of the t least one silicon precursor of Formula I is 40° C. or less, 30° C. or less, or 20° C. or less, or 10° C. or less. Alternatively, the difference between the boiling points ranges from any one or more of the following end-points: 0, 10, 20, 30, or 40° C. Examples of suitable ranges of b.p. difference include without limitation, 0 to 40° C., 20° to 30° C., or 10° to 30° C. Examples of suitable solvents in the compositions include, but are not limited to, an ether (such as 1,4-dioxane, dibutyl ether), a tertiary amine (such as pyridine, 1-methylpiperidine, 1-ethylpiperidine, N,N′-Dimethylpiperazine, N,N,N′,N′-Tetramethylethylenediamine), a nitrile (such as benzonitrile), an alkane (such as octane, nonane, dodecane, ethylcyclohexane), an aromatic hydrocarbon (such as toluene, mesitylene), a tertiary aminoether (such as bis(2-dimethylaminoethyl) ether), or mixtures thereof.

As previously mentioned, the purity level of the at least one silicon precursor of Formula I is sufficiently high to be acceptable for reliable semiconductor manufacturing. In certain embodiments, the at least one silicon precursor of Formula I described herein comprises less than 2% by weight, or less than 1% by weight, or less than 0.5% by weight of one or more of the following impurities: free amines, free halides or halogen ions, and higher molecular weight species. Higher purity levels of the silicon precursor described herein can be obtained through one or more of the following processes: purification, adsorption, and/or distillation.

In one embodiment of the method described herein, a cyclic deposition process such as ALD-like, ALD, or PEALD may be used wherein the deposition is conducted using the at least one silicon precursor of Formula I and an oxygen source. The ALD-like process is defined as a cyclic CVD process but still provides high conformal silicon oxide films.

In certain embodiments, the gas lines connecting from the precursor canisters to the reaction chamber are heated to one or more temperatures depending upon the process requirements and the container of the at least one silicon precursor of Formula I is kept at one or more temperatures for bubbling. In other embodiments, a solution comprising the at least one silicon precursor of Formula I is injected into a vaporizer kept at one or more temperatures for direct liquid injection.

A flow of argon and/or other gas may be employed as a carrier gas to help deliver the vapor of the at least one silicon precursor of Formula I to the reaction chamber during the precursor pulsing. In certain embodiments, the reaction chamber process pressure is about 1 Torr.

In a typical ALD or an ALD-like process such as a CCVD process, the substrate such as a silicon oxide substrate is heated on a heater stage in a reaction chamber that is exposed to the silicon precursor initially to allow the complex to chemically adsorb onto the surface of the substrate.

A purge gas such as argon purges away unabsorbed excess complex from the process chamber. After sufficient purging, an oxygen source may be introduced into reaction chamber to react with the absorbed surface followed by another gas purge to remove reaction by-products from the chamber. The process cycle can be repeated to achieve the desired film thickness. In some cases, pumping can replace a purge with inert gas or both can be employed to remove unreacted silicon precursors.

In this or other embodiments, it is understood that the steps of the methods described herein may be performed in a variety of orders, may be performed sequentially, may be performed concurrently (e.g., during at least a portion of another step), and any combination thereof. The respective step of supplying the precursors and the oxygen source gases may be performed by varying the duration of the time for supplying them to change the stoichiometric composition of the resulting dielectric film such as silicon oxide.

One particular embodiment of the method described herein to deposit a silicon oxide film via an ALD or ALD-like on a substrate comprises the following steps:
a. providing a substrate in a reactor
b. introducing into the reactor at least one silicon precursor described herein having Formula I wherein the at least one silicon precursor is substantially free of one or more impurities selected from the group consisting of halide compounds, metal ions, metals, and combinations thereof
c. purging reactor with purge gas
d. introducing oxygen source into the reactor and
e. purging reactor with purge gas
   wherein steps b through e are repeated until a desired thickness of the silicon oxide film is deposited. The silicon oxide film is high quality silicon oxide which has a leakage current about 2.0e⁻⁸ A/cm² or lower at 2.5 MW/cm, or about 2.0e⁻⁹ A/cm² or lower at 2.5 MV/cm², or about 1.0e⁻⁹ A/cm² or lower at 2.5 MV/cm².

In certain embodiments, the resulting silicon oxide film is exposed to one or more post-deposition treatments such as, but not limited to, a plasma treatment, thermal treatment, chemical treatment, ultraviolet light exposure, electron beam exposure, and combinations thereof to affect one or more properties of the films. These post-deposition treatments may occur under an atmosphere selected from inert, oxidizing, and/or reducing.

More particularly, the post-deposition treatments may include plasma treatments (in-situ, remote or combinations thereof); thermal anneals (heating at a temperature ranging from 100° C. to 1050° C.) in the presence of a ultra-high purity inert gas (i.e. N₂, He, Ne, Ar); reactive thermal anneals including heating in the presence of plasma-generated species, reactive species such as ammonia, hydrogen, a allylamine, a propargylamine, a vinylamine, hydrazine, a hydrazine derivative, oxygen, ozone, water and/or hydrogen peroxide; radiation treatments under inert gas in ambient or vacuum pressure; reactive radiation treatments, in the presence of any of the same species as mentioned for reactive thermal anneals, such reactive radiation treatments including UV curing (at a wavelength ≤400 nm, preferably <300 nm, more preferably, <250 nm) and reactive UV curing.

### EXAMPLES

### Example 1: Evaluation of the Thermal Stability of DSBAS as a Function of Chloride Concentration

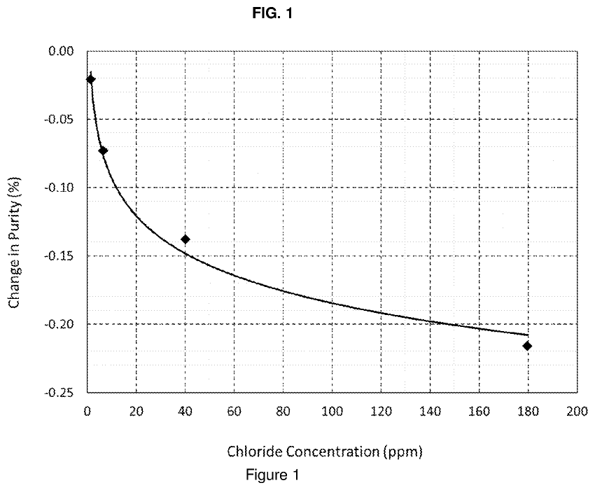

Two samples of DSBAS (di-sec-butylaminosilane) were analyzed by GC-TCD to have purities of 99.65% and 99.57%, and by ICP to have chloride concentrations (chloride contents) of 1.4 ppm and 179.7 ppm, respectively. These two samples were mixed in appropriate proportions to make two new samples of DSBAS with intermediate chloride concentrations of 6.5 ppm and 40.1 ppm, respectively in a nitrogen containing glovebox. The resulting four samples of DSBAS, arranged in order of increasing chloride concentration, were designated as DSBAS #1, DSBAS #2, DSBAS #3 and DSBAS #4. Approximately 2.0 ml samples of DSBAS #1 were added to each of two stainless steel tubes in a nitrogen containing glovebox. This was repeated for DSBAS #2, DSBAS #3 and DSBAS #4 to make up a total of 8 stainless steel tubes with DSBAS samples. The tubes were capped and placed into a lab oven and heated at 80° C. for 7 days. The purpose of heating the samples for 7 days at 80° C. is to subject the DSBAS to accelerated ageing conditions that would simulate the normal ageing that would occur after 1 year at ambient temperature (22° C.). The 8 heated samples were analyzed by GC to determine the extent of degradation relative to the unheated control samples. The heated samples of DSBAS #1, DSBAS #2, DSBAS #3 and DSBAS #4 showed average decreases in purity by GC of 0.021%, 0.073%, 0.138% and 0.216%, respectively, relative to the unheated control samples. The chloride data and the before/after GC purity data are summarized in Table 1. FIG. 1 shows a plot of the change in purity of DSBAS as a result of the heat treatment as a function of the chloride content. The before/after GC data show that the DSBAS stability improves with decreasing chloride content.

TABLE 1
Summary of the chloride and GC purity data for DSBAS #1,
DSBAS #2, DSBAS #3 and DSBAS #4.

| | Chloride | Average GC | Average GC | Change |
|---|---|---|---|---|
| | concentration | purity before | purity after | in purity |
| Description | (ppm) | heat (%) | heat (%) | (%) |
| DSBAS #1 | 1.4 | 99.647 | 99.626 | −0.021 |
| DSBAS #2 | 6.5 | 99.674 | 99.601 | −0.073 |
| DSBAS #3 | 40.1 | 99.598 | 99.460 | −0.138 |
| DSBAS #4 | 179.7 | 99.568 | 99.352 | −0.216 |

### Example 2: Atomic Layer Deposition of Silicon Oxide Films with Di-sec-butylaminosilane with Various Chloride Impurities

Atomic layer deposition of silicon oxide films were conducted using the following precursors: di-sec-butylaminosilane (DSBAS) with chloride level of 1.4 ppm, 11.0 ppm, and 179.7 ppm.

The depositions were performed on a laboratory scale ALD processing tool. The silicon precursor was delivered to the chamber by vapor draw. Each container, containing a different chloride level, was used for 2 depositions at 300° C. followed by 2 depositions at 500° C. All gases (e.g., purge and reactant gas or precursor and oxygen source) were preheated to 100° C. prior to entering the deposition zone. Gases and precursor flow rates were controlled with ALD diaphragm valves with high speed actuation. The substrates used in the deposition were 12 inch long silicon strips. A thermocouple attached on the sample holder to confirm substrate temperature. Depositions were performed using ozone as oxygen source gas. Deposition parameters are provided in Table 2.

TABLE 2
Process for Atomic Layer Deposition of Silicon Oxide
Films with Ozone Using DSBAS as Silicon Precursor

| Steps | Descriptions | Time | | Notes |
|---|---|---|---|---|
| 1 | Insert Si substrates | | | |
| | into a reactor | | | |
| 2 | Heat substrates to | ~1-2 | | T = 300° C. and 600° C. |
| | desired temperature | hours | | |
| 3 | Close throttle valve | 2 seconds | | Throttle valve is closed |
| | | (s) | | to increase residence time |
| 4 | Flow Si precursor | 1 | s | Vapor draw; Chamber |
| | into reactor | | | pressure was 0.1-0.2 Torr |
| 5 | Open throttle valve | 2 | s | |
| 6 | Flow N₂ to purge | 6 | s | N₂ flow is 5 lpm |
| | the reactor | | | |
| 7 | Evacuate the reactor | 6 | s | Base pressure is <1 mTorr |
| | to base pressure | | | |
| 8 | Flow Ozone to the | 10 | s | Pressure is set to 5 Torr; |
| | reactor | | | Ozone concentration is 16- |
| | | | | 20 wt %; Ozone flow = 800 |
| | | | | sccm |
| 9 | Flow N₂ to purge | 6 | s | N₂ flow is 5 lpm |
| | the reactor | | | |
| 10 | Evacuate the reactor | 6 | s | Base pressure is <1 mTorr |
| | to base pressure | | | |
| 11 | Remove Si sample | | | Temperature <200° C. for |
| | from the reactor | | | this process |

Steps 3-10 are repeated until a desired thickness is reached. Thickness and refractive indices of the films were measured using a FilmTek 2000SE ellipsometer by fitting the reflection data from the film to a pre-set physical model (e.g., the Lorentz Oscillator model). The % non-uniformity was calculated from 6-point measurements using the following equation: % non-uniformity=((max−min)/(2*mean)).

Electrical properties were characterized by building metal-insulator capacitor (MISCAP) devices. Each deposition has 12 leakage current measurements from MISCAP devices. Leakage current at 2.5 MV/cm are compared to elucidate electrical properties differences among films deposited with DSBAS with different chloride level.

Table 3 and Table 4 show leakage current at 2.5 MV/cm for film deposited at 300° C. and 500° C. respectively. In both 300° C. and 500° C. depositions, higher chloride concentrations in DSBAS translates to at least an order of magnitude leakage current. This translates to higher RC delay and detrimental to the device performance, i.e. the lower the leak current is, the less the device fails. Importantly Table 4 demonstrating higher deposition temperatures such as 500° C. provide better high quality silicon oxide films than lower deposition temperatures such as 300° C., i.e. the leak currents at 500° C. are 10 times better than those deposited at 300° C.

TABLE 3
Leakage currents at 2.5 MV/cm for high quality
silicon oxide films deposited at 300° C.

| Deposition | | Leakage current |
|---|---|---|
| temperature | Chloride level | at 2.5 MV/cm |
| (° C.) | (ppm) | (A/cm²) |
| 300 | 1.4 | 1.8E−8-3.8E−8 |
| 300 | 118.0 | 1.9E−7-7.2E−7 |
| 300 | 179.7 | 2.1E−7-9.3E−7 |

TABLE 4
Leakage currents at 2.5 MV/cm for high quality
silicon oxide film deposited at 500° C.

| Deposition | | Leakage current |
|---|---|---|
| temperature | Chloride level | at 2.5 MV |
| (° C.) | (ppm) | (A/cm²) |
| 500 | 1.4 | 1.3E−9-2.0E−9 |
| 500 | 118.0 | 4.8E−9-3.2E−8 |
| 500 | 179.7 | 1.8E−8-7.4E−6 |

Although illustrated and described above with reference to certain specific embodiments and examples, the present invention is nevertheless not intended to be limited to the details shown. Rather, various modifications may be made in the details within the scope and range of equivalents of the claims and without departing from the spirit of the invention. It is expressly intended, for example, that all ranges broadly recited in this document include within their scope all narrower ranges which fall within the broader ranges.

1. A process for depositing a high quality silicon oxide film comprising the steps of:
a. providing a substrate in a reactor;
b. introducing into the reactor at least one silicon precursor wherein the at least one silicon precursor has a structure represented by H₃SiNR¹R² wherein R¹ and R² are each independently selected from a C₁₋₁₀ linear alkyl group, a C₃₋₁₀ branched alkyl group, a C₃₋₁₀ cyclic alkyl group, a C₂₋₁₀ alkenyl group, a C₄₋₁₀ aromatic group, a C₄₋₁₀ heterocyclic group with a provisio that R¹ and R² cannot be both C₁₋₂ linear alkyl group or C₃ branched alkyl group, and wherein the at least one silicon precursor is substantially free of one or more impurities selected from the group consisting of halide compounds, metal ions, metals, and combinations thereof;
c. purging reactor with purge gas;
d. introducing an oxygen source into the reactor;
e. purging reactor with purge gas;
wherein steps b through e are repeated until desired thickness is deposited, and
wherein process temperature ranges from 20 to 600° C. and pressure in the reactor ranges from 50 milliTorr (mT) to 760 Torr.

2. The process of claim 1, wherein the at least one silicon precursor is selected from the group consisting of di-sec-butylaminosilane, di-tert-butylaminosilane, phenylmethylaminosilane, phenylethylaminosilane, cyclohexamethylaminosilane, cyclohexaethylaminosilane, 2,6-dimethylpiperidinosilane, 2,5-dimethylpyrrolylsilane and mixtures thereof.

3. The process of claim 1, wherein the halide compounds in the silicon precursor comprise chloride compounds.

4. The silicon precursor of claim 3, wherein the chloride compounds, if present, are present at a concentration of 10 ppm chloride or less as measured by IC.

5. The silicon precursor of claim 3, wherein the chloride compounds, if present, are present at a concentration of 5 ppm chloride or less as measured by IC.

6. The silicon precursor of claim 3, wherein the chloride compounds, if present, are present at a concentration of 1 ppm chloride or less as measured by IC.

7. The process of claim 1, wherein the purge gas is selected from the group consisting of nitrogen, helium, and argon.

8. The process of claim 1, wherein the oxygen source is selected from the group consisting of oxygen, peroxide, oxygen plasma, water vapor, water vapor plasma, hydrogen peroxide, and ozone source.

9. A silicon oxide film produced by the process of claim 1.

10. The silicon oxide film of claim 9 wherein the film has a leakage current about 2.0e⁻⁸ A/cm² or lower at 2.5 MW/cm, or about 2.0e⁻⁹ A/cm² or lower at 2.5 MV/cm², or about 1.0e⁻⁹ A/cm² or lower at 2.5 MV/cm².

11. A composition for depositing a high quality silicon oxide film comprising at least one silicon precursor wherein the at least one silicon precursor has a structure represented by H₃SiNR¹R² wherein R¹ and R² are each independently selected from a C₁₋₁₀ linear alkyl group, a C₃₋₁₀ branched alkyl group, a C₃₋₁₀ cyclic alkyl group, a C₂₋₁₀ alkenyl group, a C₄₋₁₀ aromatic group, a C₄₋₁₀ heterocyclic group with a provisio that R¹ and R² cannot be both C₁₋₂ linear alkyl group or C₃ branched alkyl group, and wherein the at least one silicon precursor is substantially free of one or more impurities selected from the group consisting of halide compounds, metal ions, metals, and combinations thereof;

12. The composition of claim 11, wherein the at least one silicon precursor is selected from the group consisting of di-sec-butylaminosilane, di-tert-butylaminosilane, phenylmethylaminosilane, phenylethylaminosilane, cyclohexamethylaminosilane, cyclohexaethylaminosilane, 2,6-dimethylpiperidinosilane, 2,5-dimethylpyrrolyl silane and mixtures thereof.

13. The composition of claim 11, wherein the halide compounds in the silicon precursor comprise chloride compounds.

14. The silicon precursor of claim 13, wherein the chloride compounds, if present, are present at a concentration of 10 ppm chloride or less as measured by IC.

15. The silicon precursor of claim 13, wherein the chloride compounds, if present, are present at a concentration of 5 ppm chloride or less as measured by IC.

16. The silicon precursor of claim 13, wherein the chloride compounds, if present, are present at a concentration of 1 ppm chloride or less as measured by IC.
